(19) United States
(12) Patent Application Publication
(10) Pub. No.: US 2019/0161853 A1
(43) Pub. Date: May 30, 2019

(54) METHOD FOR FORMING TUNGSTEN FILM

(71) Applicant: TOKYO ELECTRON LIMITED, Tokyo (JP)

(72) Inventors: Shintaro Aoyama, Nirasaki City, Yamanashi (JP); Mikio Suzuki, Nirasaki City, Yamanashi (JP); Yumiko Kawano, Nirasaki City, Yamanashi (JP); Kohichi Satoh, Nirasaki City, Yamanashi (JP)

(21) Appl. No.: 16/312,864

(22) PCT Filed: Jul. 11, 2017
(86) PCT No.: PCT/JP2017/025251

§ 371 Date: Dec. 21, 2018

(30) Foreign Application Priority Data
Jul. 26, 2016 (JP) 2016-146089

(51) Int. Cl. C23C 16/02; C23C 16/14; C23C 16/24; H01L 21/285

(52) U.S. Cl. CPC C23C 16/0209; C23C 16/14; C23C 16/0272; H01L 21/28556; C23C 16/24

(57) ABSTRACT

Provided is a method for forming a tungsten film in which a tungsten film is formed on the surface of a substrate, the method including: disposing a substrate having an amorphous layer on the surface thereof inside a treatment container under a depressurized atmosphere; heating the substrate inside the treatment container; and supplying, into the treatment container, WF₆ gas which is a tungsten raw material and H₂ gas which is a reducing gas, and forming a main tungsten film on the amorphous layer.

### FIELD OF THE INVENTION

The present invention relates to a method for forming a tungsten film.

### BACKGROUND OF THE INVENTION

In manufacturing Large Scale Integration (LSI) technology, tungsten is widely used in a gate electrode of a MOSFET (Metal Oxide Silicon Field Effect Transistor), contact between a source and a drain, a word line of a memory, and the like. In a multi-layer wiring process, copper wiring is mainly used. However, copper is insufficient in heat resistance and easily diffuses, so tungsten is used in regions requiring heat resistance, regions where electrical characteristics may deteriorate due to diffusion of copper, and the like.

A physical vapor deposition (PVD) method has been used for a tungsten film forming process. However, in a region that requires high step coverage, it may be difficult for the PVD method to achieve high step coverage. Therefore, film formation has been performed using a chemical vapor deposition (CVD) method capable of achieving high step coverage.

In a tungsten film (CVD-tungsten film) forming method using the CVD method, for example, a tungsten hexafluoride (WF₆) gas as a source gas and H₂ gas as a reducing gas are generally used to cause a reaction of WF₆₊₃H₂→W+6HF on a semiconductor wafer as a target substrate (see, e.g., Japanese Patent Application Publication Nos. 2003-193233 and 2004-273764).

In Japanese Patent Application Publication Nos. 2003-193233 and 2004-273764, before the main film formation of the tungsten film by the above reaction, a nucleation process is performed so that the tungsten film can be uniformly formed. At this time, an atomic layer deposition (ALD) method, in which a source gas and a reducing gas, e.g., SiH₄ gas or B₂H₆ gas having a reducing power greater than that of H₂ gas, are sequentially supplied with purging interposed therebetween, is employed to form a dense film.

Due to the recent progress of the miniaturization of semiconductor devices, the ALD method is also used for the main film formation of tungsten film (main tungsten film) to achieve higher step coverage.

However, in the case of forming the main tungsten film by a CVD method or an ALD method using tungsten hexafluoride (WF₆) and H₂ gas as a reducing gas, the formed tungsten film may not have sufficiently low resistance. Therefore, it is required to reliably make the formed tungsten film with sufficiently low resistance.

### SUMMARY OF THE INVENTION

In view of the above, the present invention provides a tungsten film forming method capable of forming a tungsten film having low resistance.

In accordance with a first aspect of the present invention, there is provided a tungsten film forming method for forming a tungsten film on a surface of a substrate, the method comprising: disposing a substrate having an amorphous layer on a surface thereof in a processing chamber under a depressurized atmosphere; heating the substrate in the processing chamber; and forming a main tungsten film on the amorphous layer by supplying into the processing chamber WF₆ gas as a tungsten source gas and H₂ gas as a reducing gas.

In accordance with a second aspect of the present invention, there is provided a tungsten film forming method for forming a tungsten film on a surface of a substrate, the method comprising: disposing a substrate in a processing chamber under a depressurized atmosphere; heating the substrate in the processing chamber; forming an initial tungsten film that is an amorphous layer on the surface of the substrate by sequentially supplying into the processing chamber WF₆ gas as a tungsten source gas and a reducing gas with purging of the processing chamber interposed therebetween; and forming a main tungsten film on the initial tungsten film by supplying into the processing chamber WF₆ gas as a tungsten source gas and H₂ gas as a reducing gas.

In the second aspect, the initial tungsten film may be formed by using B₂H₆ gas as the reducing gas. Further, the initial tungsten film may also be formed by using a gaseous mixture of B₂H₆ gas and SiH₄ gas, or a gaseous mixture of B₂H₆ gas, SiH₄ gas and H₂ gas as the reducing gas.

In the second aspect, the tungsten film forming method may further comprise, before the forming the initial tungsten film that is the amorphous layer, performing an initiation process for facilitating the formation of the initial tungsten film that is the amorphous layer.

In accordance with a third aspect of the present invention, there is provided a tungsten film forming method for forming a tungsten film on a surface of a substrate, the method comprising: disposing a substrate in a processing chamber under a depressurized atmosphere; heating the substrate in the processing chamber; forming an initial tungsten film that is a crystalline layer on the surface of the substrate by sequentially supplying WF₆ gas as a tungsten source gas and a reducing gas into the processing chamber with purging of the processing chamber interposed therebetween; forming an amorphous layer on the initial tungsten film; and forming a main tungsten film on the amorphous layer by supplying WF₆ gas as a tungsten source gas and H₂ gas as a reducing gas into the processing chamber.

In the third aspect, the initial tungsten film may be formed by using SiH₄ gas as the reducing gas. Further, a gas containing a material of the amorphous layer may be a gaseous mixture of B₂H₆ gas and H₂ gas, or a gaseous mixture of B₂H₆ gas, H₂ gas and WF₆ gas, and the amorphous layer may be an amorphous boron film or an amorphous tungsten film.

In the third aspect, the tungsten film forming method of claim 15 may further comprise, before the forming the initial tungsten film, performing an initiation process for facilitating the formation of the initial tungsten film on the surface of the substrate. The initiation process may be performed on the surface of the substrate by supplying SiH₄ gas, or a gaseous mixture of SiH₄ gas and H₂ gas, or B₂H₆ gas, or a gaseous mixture of B₂H₆ gas and H₂ gas.

In accordance with a fourth aspect of the present invention, there is provided a tungsten film forming method for forming a tungsten film on a surface of a substrate, the method comprising: disposing a substrate in a processing chamber under a depressurized atmosphere; heating the substrate in the processing chamber; forming an amorphous layer on the surface of the substrate; and forming a main tungsten film on the amorphous layer by supplying WF₆ gas as a tungsten source gas and H₂ gas as a reducing gas into the processing chamber.

In the fourth aspect, a gas for forming the amorphous layer may be SiH₄ gas or B₂H₆ gas, or a gaseous mixture thereof, and the amorphous layer may be an amorphous silicon film or an amorphous boron film.

In the first to the fourth aspect, the substrate may have a TiN film on the surface thereof.

In accordance with a fifth aspect of the present invention, there is provided a tungsten film forming method for forming a tungsten film on a surface of a substrate, the method comprising: preparing a substrate; forming an amorphous layer on the surface of the substrate; heating the substrate in a processing chamber under a depressurized atmosphere; and forming a main tungsten film on the amorphous layer by supplying WF₆ gas as a tungsten source gas and H₂ gas as a reducing gas into the processing chamber.

In the fifth aspect, the tungsten film forming method may further comprise, before the forming the main tungsten film, performing an initiation process for facilitating the formation of the main tungsten film on the amorphous layer formed on the surface of the substrate. The forming the amorphous layer on the substrate and the forming the main tungsten film are performed in-situ. The substrate may have a TiSiN film on the surface thereof. The initiation process may be performed on the surface of the substrate by supplying SiH₄ gas, or a gaseous mixture of SiH₄ gas and H₂ gas, or B₂H₆ gas, or a gaseous mixture of B₂H₆ gas and H₂ gas.

In the first to the fifth aspect, the substrate may be heated is to a temperature of 300° C. to 500° C., particularly, a temperature of 350° C. to 450° C.

In the first to the fifth aspect, the main tungsten film may be formed by sequentially supplying WF₆ gas as the tungsten source gas and H₂ gas as the reducing gas into the processing chamber with purging of the processing chamber interposed therebetween.

In accordance with a sixth aspect of the present invention, there is provided a storage medium storing a program that is executed on a computer to control a film forming apparatus, wherein the program, when executed on the computer, controls the film forming apparatus to perform the tungsten film forming method of any one of the first to the fifth aspect.

### Effect of the Invention

In accordance with the present invention, by forming the main tungsten film on the amorphous layer, the number of nuclei of tungsten can be reduced and, thus, the crystal grain size can be increased. Further, the resistance of the tungsten film can be lowered.

### BRIEF DESCRIPTION OF THE DRAWINGS

FIG. 1 is a cross sectional view showing an example of a film forming apparatus for performing a tungsten film forming method according to the present invention.

FIG. 2 is a flowchart of a first embodiment of the tungsten film forming method according to the present invention.

FIGS. 3A to 3D are process cross-sectional views showing a procedure of the film forming method according to the first embodiment of the present invention.

FIG. 4 shows results of X-ray diffraction (XRD) in the case of performing processes up to the formation of an initial tungsten film and in the case of performing processes up to the formation of a main tungsten film in a sample B.

FIG. 5A is an SEM image of the sample A.

FIG. 5B is an SEM image of the sample B.

FIG. 6 shows planar TEM images of the sample A and the sample B.

FIG. 7 shows minimum particle diameters, maximum particle diameters, and average particle diameters of the sample A and the sample B in the planar TEM images shown in FIG. 6.

FIG. 8 explains a first example of the first embodiment.

FIG. 9 is a timing chart showing gas introduction timing in forming an amorphous layer in the first example of the first embodiment.

FIG. 10 is a timing chart showing gas introduction timing in forming a main tungsten film in the first example of the first embodiment.

FIG. 11 explains a second example of the first embodiment.

FIG. 12 is a timing chart showing gas introduction timing in forming an amorphous layer in the second example of the first embodiment.

FIG. 13 is a flowchart of a film forming method according to a second embodiment of the present invention.

FIGS. 14A to 14E are process cross-sectional views showing a procedure of the film forming method according to the second embodiment of the present invention.

FIG. 15 explains a specific example of the second embodiment.

FIG. 16 is a flowchart of a film forming method according to a third embodiment of the present invention.

FIGS. 17A to 17C are process cross-sectional views showing a procedure of the film forming method according to the third embodiment of the present invention.

FIG. 18 explains a specific example of the third embodiment.

FIG. 19 is a flowchart of a film forming method according to a fourth embodiment of the present invention.

FIGS. 20A to 20C are process cross-sectional views showing a procedure of the film forming method according to the fourth embodiment of the present invention.

FIG. 21 explains a specific example of the fourth embodiment.

### DETAILED DESCRIPTION OF THE EMBODIMENTS

As a result of extensive studies to achieve the above-mentioned objects, the present inventors have found that crystal grains of a main tungsten film can be increased by forming the main tungsten film on an amorphous film and the low resistance of the tungsten film can be achieved, and have conceived the present invention.

Hereinafter, embodiments of the present invention will be described in detail with reference to the accompanying drawings.

<Example of Film Forming Apparatus>

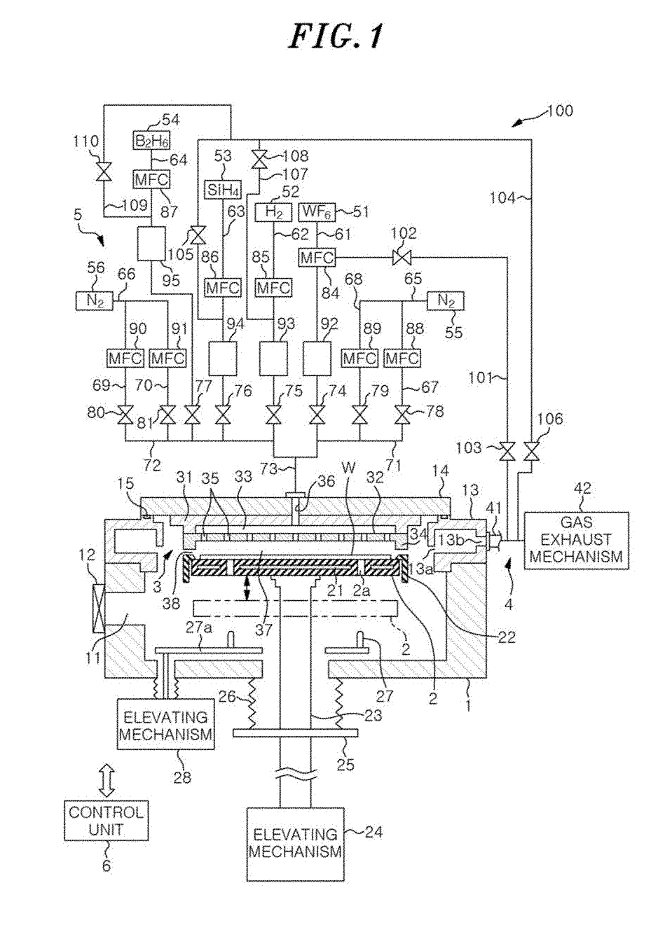

FIG. 1 is a cross sectional view showing an example of a film forming apparatus for performing a tungsten film forming method of the present invention. This apparatus is suitable for forming a tungsten film by an ALD method.

As shown in FIG. 1, a film forming apparatus 100 includes a chamber 1, a susceptor 2 for horizontally supporting a semiconductor wafer (hereinafter, simply referred to as “wafer”) W as a target substrate in the chamber 1, a shower head 3 for supplying a processing gas in a shower shape into the chamber 1, a gas exhaust unit 4 for exhausting the chamber 1, a processing gas supply unit 5 for supplying the processing gas to the shower head 3, and a control unit 6.

The chamber 1 is made of a metal such as aluminum or the like and has a substantially cylindrical shape. A loading/unloading port 11 for loading/unloading the wafer W is formed at the sidewall of the chamber 1. The loading/unloading port 11 can be opened and closed by a gate valve 12. An annular gas exhaust duct 13 having a rectangular cross section is provided on the main body of the chamber 1. A slit 13a is formed along the inner peripheral surface of the gas exhaust duct 13. A gas exhaust port 13b is formed at the outer wall of the gas exhaust duct 13. A ceiling plate 14 is provided on the upper surface of the gas exhaust duct 13 to block the upper opening of the chamber 1. A gap between the ceiling plate 14 and the gas exhaust duct 13 is hermetically sealed by a sealing ring 15.

The susceptor 2 is formed in a disc shape having a size corresponding to that of the wafer W, and is supported by a support member 23. The susceptor 2 is made of ceramic material such as aluminum nitride (AlN) or the like, or metal such as aluminum, a nickel-based alloy or the like. A heater 21 for heating the wafer W is embedded in the susceptor 2. The heater 21 is configured to generate heat by power supplied from a heater power supply (not shown). The temperature of the wafer W is controlled to a predetermined level by controlling the output of the heater 21 by a temperature signal of a thermocouple (not shown) provided near a wafer mounting surface on the upper surface of the susceptor 2.

A cover member 22 made of ceramic such as alumina or the like is provided at the susceptor 2 to cover the outer peripheral region of the wafer mounting surface and the side surface of the susceptor 2.

The support member 23 supporting the susceptor 2 extends downward from a center of a bottom surface of the susceptor 2 to a position below the chamber 1 while penetrating through a hole formed in a bottom portion of the chamber 1. The lower end of the support member 23 is connected to an elevating mechanism 24. The susceptor 2 can be raised and lowered by the elevating mechanism 24 between a processing position shown in FIG. 1 and a transfer position where the wafer can be transferred as indicated by a dashed dotted line which is positioned below the processing position. Below the chamber 1, a shield part 25 is provided at a lower portion of the support member 23. Provided between the bottom surface of the chamber 1 and the shield portion 25 is a bellows 26 that partitions an atmosphere in the chamber 1 from exterior air and that is extensible and contractible by the elevating operation of the susceptor 2.

Three wafer supporting pins 27 (only two being shown) are provided near the bottom surface of the chamber 1 to protrude upward from an elevating plate 27a. The wafer supporting pins 27 can be lifted and lowered through the elevating plate 27a by an elevating mechanism 28 provided below the chamber 1. Further, the wafer supporting pins 27 can protrude beyond and retract below the top surface of the susceptor 2 while being inserted into through-holes 2a formed in the susceptor 2 positioned at the transfer position. By lifting and lowering the wafer support pins 27, the wafer W is transferred between a wafer transfer mechanism (not shown) and the susceptor 2.

The shower head 3 is made of metal and is provided to face the susceptor 2. The shower head 3 has substantially the same diameter as that of the susceptor 2. The shower head 3 has a main body 31 fixed to the ceiling plate 14 of the chamber 1, and a shower plate 32 connected to the bottom of the main body 31. A gas diffusion space 33 is formed between the main body 31 and the shower plate 32. A gas inlet hole 36 penetrating through the center portions of the main body 31 and the ceiling plate 14 of the chamber 1 is connected to the gas diffusion space 33. An annular protrusion 34 protruding downward is formed at the peripheral portion of the shower plate 32. Gas injection holes 35 are formed on the flat surface of the shower plate 32 inward of the annular protrusion 34.

In a state where the susceptor 2 is located at the processing position, a processing space 37 is formed between the shower plate 32 and the susceptor 2. In that state, the annular protrusion 34 and the top surface of the cover member 22 of the susceptor 2 become close to each other to form an annular gap 38.

The gas exhaust unit 4 includes a gas exhaust line 41 connected to the gas exhaust port 13b of the gas exhaust duct 13, and a gas exhaust mechanism 42 connected to the gas exhaust line 41 and having a vacuum pump, a pressure control valve and the like. During the processing, the gas in the chamber 1 reaches the gas exhaust duct 13 through the slit 13a and is exhausted from the gas exhaust duct 13 through the gas exhaust line 41 by the gas exhaust mechanism 42 of the gas exhaust unit 4.

The processing gas supply unit 5 includes: a WF₆ gas supply source 51 for supplying WF₆ gas as a tungsten source gas; an H₂ gas supply source 52 for supplying H₂ gas as a reducing gas; an SiH₄ gas supply source 53 for supplying SiH₄ gas; a B₂H₆ gas supply source 54 for supplying B₂H₆ gas; and a first and a second N₂ gas supply source 55 and 56 for supplying N₂ gas as a purge gas. The processing gas supply unit 5 further includes: a WF₆ gas supply line 61 extending from the WF₆ gas supply source 51; an H₂ gas supply line 62 extending from the H₂ gas supply source 52; an SiH₄ gas supply line 63 extending from the SiH₄ gas supply source 53; a B₂H₆ gas supply line 64 extending from the B₂H₆ gas supply source 54; a first N₂ gas supply line 64 extending from the first N₂ gas supply source 55 and configured to supply N₂ gas to the WF₆ gas supply line 61; and a second N₂ gas supply line 66 extending from the second N₂ gas supply source 56 and configured to supply N₂ gas to the H₂ gas supply line 62.

The first N₂ gas supply line 65 is branched to a first continuous N₂ gas supply line 67 for constantly supplying N₂ gas during the film formation using the ALD method and a first flush purge line 68 for supplying N₂ gas only during the purge process. The second N₂ gas supply line 66 is branched to a second continuous N₂ gas supply line 69 for constantly supplying N₂ gas during the film formation using the ALD method and a second flush purge line 70 for supplying N₂ gas only during the purge process. The first continuous N₂ gas supply line 67 and the first flush purge line 68 are connected to a first connection line 71. The first connection line 71 is connected to the WF₆ gas supply line 61. The SiH₄ gas supply line 63, the B₂H₆ gas supply line 64, the second continuous N₂ gas supply line 69 and the second flush purge line 70 are connected to a second connection line 72. The second connection line 72 is connected to the H₂ gas supply line 62. The WF₆ gas supply line 61 and the H₂ gas supply line 62 are joined with a joint line 73. The joint line 73 is connected to the above-described gas inlet hole 36.

The WF₆ gas supply line 61, the H₂ gas supply line 62, the SiH₄ gas supply line 63, the B₂H₆ gas supply line 64, the first continuous N₂ gas supply line 67, the first flush purge line 68, the second continuous N₂ gas supply line 69 and the second flush purge line 70 are provided with opening/closing valves 74, 75, 76, 77, 78, 79, 80 and 81 for switching gases at the time of performing ALD, respectively. Mass flow controllers 84, 85, 86, 87, 88, 89, 90 and 91 as flow rate controllers are provided at the upstream sides of the opening/closing valves of the WF₆ gas supply line 61, the H₂ gas supply line 62, the SiH₄ gas supply line 63, the B₂H₆ gas supply line 64, the first continuous N₂ gas supply line 67, the first flush purge line 68, the second continuous N₂ gas supply line 69 and the second flush purge line 70, respectively. The WF₆ gas supply line 61, the H₂ gas supply line 62, the SiH₄ gas supply line 63 and the B₂H₆ gas supply line 64 are provided with buffer tanks 92, 93, 94 and 95, respectively, so that required gases can be supplied within a short period of time.

N₂ gas is continuously supplied from the first continuous N₂ gas supply line 67 and the second continuous N₂ gas supply line 69 during the film formation of the tungsten film. N₂ gas as a purge gas is supplied from the first flush purge line 68 and the second flush purge line 70 only during the purge process at the time of performing ALD. Instead of N₂ gas, another inert gas such as Ar gas or the like may be used.

One end of a bypass line 101 is connected to the downstream side of the mass flow controller 84 in the WF₆ gas supply line 61. The other end of the bypass line 101 is connected to the gas exhaust line 41. Opening/closing valves 102 and 103 are provided in the bypass line 101 at positions near the WF₆ gas supply line 61 and the gas exhaust line 41, respectively. One end of the bypass line 104 is connected to the downstream side of the mass flow controller 86 in the SiH₄ gas supply line 63. The other end of the bypass line 104 is connected to the gas exhaust line 41. Opening/closing valves 105 and 106 are provided in the bypass line 104 at positions near the SiH₄ gas supply line 63 and the gas exhaust line 41, respectively. One ends of the bypass lines 107 and 109 are respectively connected to the downstream side of the mass flow controller 85 in the H₂ gas supply line 62 and the downstream side of the mass flow controller 87 in the B₂H₆ gas supply line 64. The other ends of the bypass lines 107 and 109 are connected to the bypass line 104. WF₆ gas, H₂ gas, SiH₄ gas, and B₂H₆ gas can bypass the chamber 1 through the respective bypass lines 101, 104, 107 and 109 to flow into the gas exhaust line 41.

The control unit 6 includes a process controller, a user interface, and a storage unit. The process controller has a microprocessor (computer) for controlling the respective components, specifically, the valve, the power supply, the heater, the pump and the like. The respective components of the film forming apparatus 100 are electrically connected to and controlled by the process controller. The user interface is connected to the process controller, and includes a keyboard through which an operator inputs commands to manage the respective components of the film forming apparatus 100, a display for visualizing and displaying operation states of the respective components of the film forming apparatus, and the like. The storage unit is also connected to the process controller, and stores a control program, i.e., a process recipe, for controlling the film forming apparatus 100 to perform a predetermined process based on processing conditions, various database and the like. The process recipe is stored in a storage medium (not shown) in the storage unit. The storage medium may be a hard disk, a CD-ROM, a DVD, a semiconductor memory, or the like. A recipe may be appropriately transmitted from another device, e.g., through a dedicated line. If necessary, a predetermined process recipe is read-out from the storage unit by an instruction from the user interface or the like and executed by the process controller. Accordingly, a desired process is performed in the film forming apparatus 100 under the control of the process controller.

<Film Forming Method>

Next, embodiments of the film forming method performed by the film forming apparatus 100 configured as described above will be described.

(First Embodiment of Film Forming Method)

First, a first embodiment of the film forming method will be described.

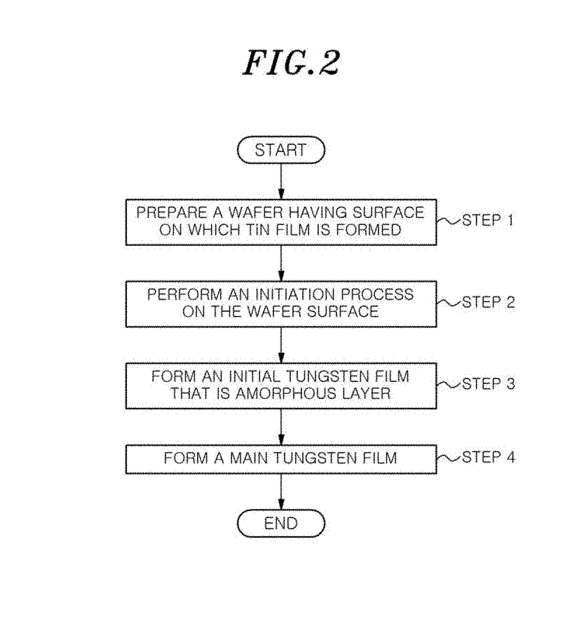

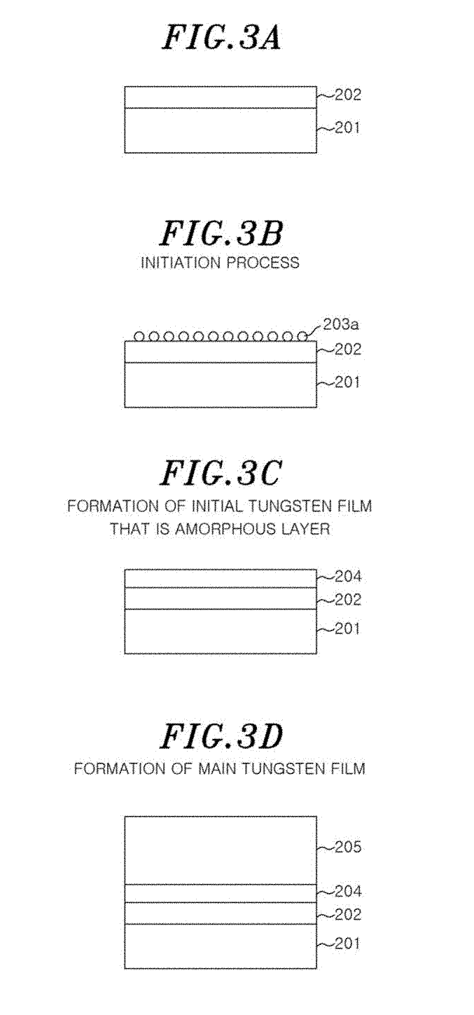

FIG. 2 is a flowchart of the first embodiment. FIGS. 3A to 3D are process cross-sectional views showing a procedure of the first embodiment.

First, a wafer in which a TiN film 202 serving as a barrier layer is formed on an interlayer insulating film 201 made of SiO₂ or the like as shown in FIG. 3A is prepared, loaded into the chamber 1 of the film forming apparatus 100, and mounted on the susceptor 2 (STEP 1). Although a recess such as a trench or a hole (contact hole or via hole) is formed in the interlayer insulating film 201, it is omitted in FIG. 3 for convenience.

Next, an atmosphere in the chamber 1 is set to a predetermined depressurized atmosphere. The wafer W on the susceptor 2 is heated to a predetermined temperature by the heater 21 in the susceptor 2, and for example, SiH₄ gas, or a gaeous mixture of SiH₄ gas and H₂ gas, or B₂H₆ gas, or a gaeous mixture of B₂H₆ gas and H₂ gas is supplied onto the wafer surface to perform an initiation process for facilitating formation of an amorphous layer as shown in FIG. 3B (STEP 2). The reducing gas is adsorbed as an adsorbate 203a by the initiation process, which facilitates the formation of an initial tungsten film in a next step. Although the initiation process facilitates the formation of the initial tungsten film, it is not necessary to perform the initiation process.

Next, in a state where the heating temperature of the susceptor 2 is maintained, an initial tungsten film 204 serving as a base of a main tungsten film is formed by a method in which WF₆ gas and a reducing gas (B₂H₆ gas, SiH₄ gas or H₂ gas) are sequentially supplied with purging of the chamber 1 interposed therebetween, e.g., an ALD method in which WF₆ gas and a reducing gas are supplied multiple times with purging of the chamber 1 interposed therebetween, from the processing gas supply mechanism 5 into the chamber 1 (STEP 3, FIG. 3C). Any of the WF₆ gas and the reducing gas may be supplied first. The initial tungsten film 204 is an amorphous layer. The film thickness of the initial tungsten film 204 is preferably 0.5 nm to 5 nm.

In this specification, the term “amorphous” means no definite crystal structure. However, very fine crystals may partially exist. Specifically, when a diffraction peak showing crystallinity is not observed or slightly observed or a halo peak is observed in the X-ray diffraction spectrum (XRD), it is determined to be amorphous.

Next, in a state where the heating temperature of the susceptor 2 is maintained, a main tungsten film 205 is formed on the initial tungsten film 204 that is an amorphous layer (STEP 4, FIG. 3D). The main tungsten film 205 fills a recess such as a trench, a hole or the like, and is formed by a method in which WF₆ gas and H₂ gas as a reducing gas are sequentially supplied with purging of the chamber 1 interposed therebetween, e.g., an ALD method in which WF₆ gas and a reducing gas are supplied multiple times with purging of the chamber 1 interposed therebetween, from the processing gas supply mechanism 5 into the chamber 1. Any of the WF₆ gas and the H₂ gas may be supplied first.

By forming the main tungsten film 205 by the method in which gases are sequentially supplied such as the ALD method, a high step coverage can be obtained. Accordingly, satisfactory fillability can be obtained even in a fine recess having a high aspect ratio. The film thickness of the main tungsten film is appropriately set depending on the size of the recess or the like, and the number of repetitions of ALD or the like is set depending on the film thickness.

When the initial tungsten film is a crystalline layer as in the conventional case, the initial tungsten film has a columnar crystal structure by the influence of the TiN film having a columnar crystal structure. If the main tungsten film is formed on the initial tungsten film, the main tungsten film also has a columnar crystal structure by the influence of the initial tungsten film. It is known that a resistance value of a crystalline substance decreases as a crystal grain diameter increases and the number of grain boundaries decreases. However, the columnar crystals have vertical grain boundaries, and the resistance of the film is not sufficiently low due to the presence of the vertical grain boundaries.

On the other hand, in the present embodiment, by forming the initial tungsten film 204 that is an amorphous layer and then forming the main tungsten film 205 on the amorphous initial tungsten film 204, the crystal grain size of the main tungsten film 205 can be increased and the resistance can be reduced.

In other word, an amorphous structure does not have grain boundaries with high energy which correspond to nucleation sites in a polycrystalline structure. Therefore, nucleation is less likely to occur and the number of nuclei decreases. Accordingly, in the case of forming the main tungsten film 205 on the initial tungsten film 204 that is an amorphous layer, each crystal grain tends to be greater and the crystal grain diameter becomes greater compared to that in the conventional case. As a result, the low resistance can be achieved.

Hereinafter, the test results that support the above conclusions will be described.

Here, a sample (sample A) was obtained by: setting a pressure in the chamber to 500 Pa and a wafer temperature to 450° C.; performing an initiation process on the TiN film for 60 sec by supplying SiH₄ gas and H₂ gas at 700 sccm and 500 sccm, respectively; forming an initial tungsten film with a film thickness of 2 nm by repeating a cycle of supplying WF₆ gas at 300 sccm for 1 sec, performing a purge process for 5 sec, supplying SiH₄ gas at 400 sccm for 1 sec and performing a purge process for 5 sec; and forming a main tungsten film with a film thickness of 19.8 nm by repeating a cycle of supplying WF₆ gas at 100 sccm for 0.15 sec, performing a purge process for 0.2 sec, supplying H₂ gas at 4500 sccm for 0.3 sec and performing a purge process for 0.3 sec. Also, a sample (sample B) was obtained by; setting the pressure and the temperature to the same conditions as those in the sample A; performing an initiation process on the TiN film by supplying B₂H₆ gas and H₂ gas at 100 sccm and 500 sccm, respectively; forming an initial tungsten film with a film thickness of 2 nm by ALD by repeating a cycle of supplying WF₆ gas at 300 sccm for 1 sec, performing a purge process for 5 sec, supplying B₂H₆ gas at 100 sccm for 1 sec and performing a purge process for 5 sec; and forming a main tungsten film with a film thickness of 15.9 nm under the same conditions as those in the sample A.

The resistivity of the sample A was 43.5 μΩ·cm and that of the sample B was 26.3 μΩ·cm. In other words, the resistivity of the sample B was lower than that of the sample A even though the main tungsten film was formed under the same conditions and the main tungsten film of the sample B was thinner than that of the sample A. This shows that the resistance can be reduced depending on the base of the main tungsten film.

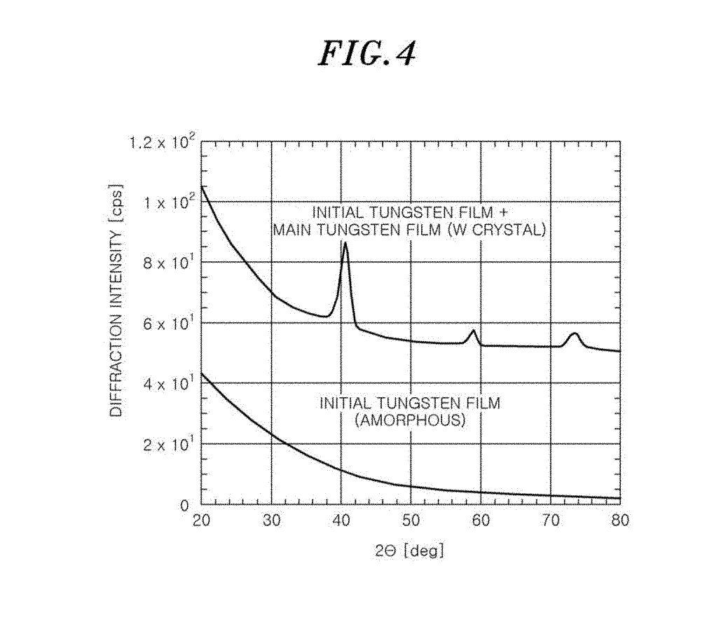

Next, X-ray diffraction (XRD) was performed on the sample B having a low resistance in the case of performing processes up to the formation of the initial tungsten film and in the case of performing processes up to the formation of the main tungsten film. The results are shown in FIG. 4. As shown in FIG. 4, a peak of tungsten crystal was observed in the case of performing processes up to the formation of the main tungsten film, whereas no diffraction peak was observed in the case of performing processes up to the formation of the initial tungsten film. From this, it is clear that the initial tungsten film is amorphous. Meanwhile, the initial tungsten film of the sample A is crystalline.

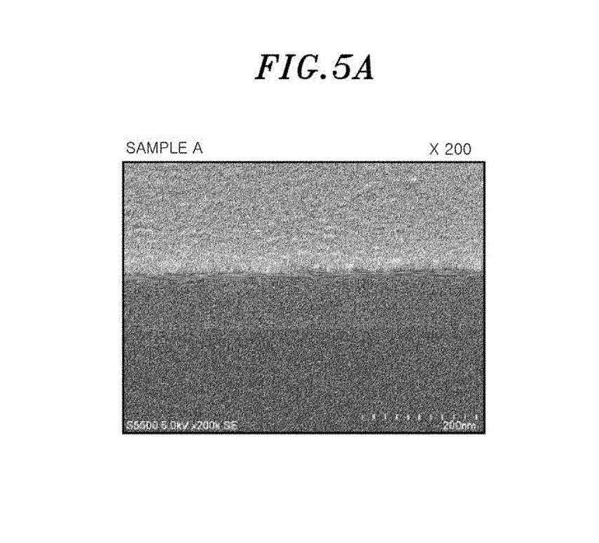

Next, the crystal states of the sample A and the sample B were monitored by SEM. FIG. 5A shows an SEM image of the sample A. FIG. 5B shows an SEM image of the sample B. As can be seen from these images, the crystal grain of the main tungsten film was greater in the sample B than in the sample A. In the sample B, a coarse grain having a maximum grain size of about 200 μm was obtained as indicated by a dashed line.

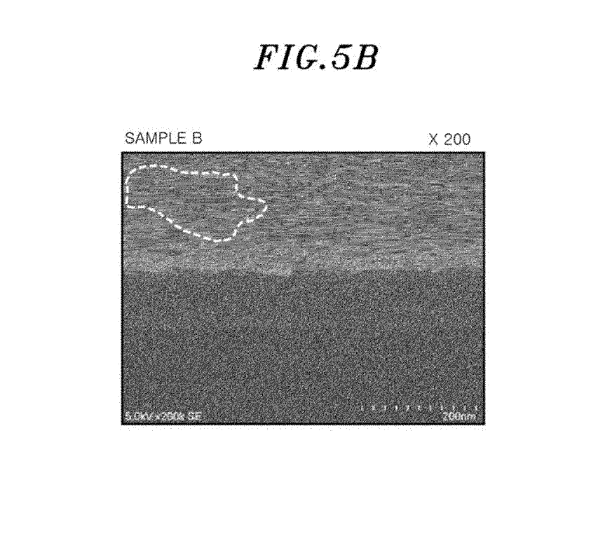

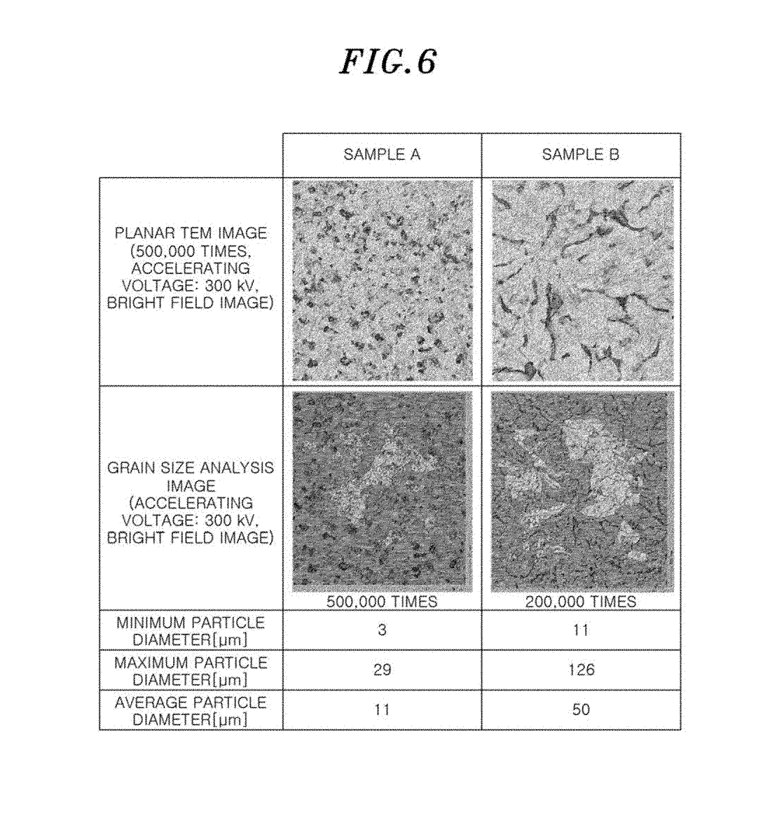

The crystal states of the sample A and the sample B were monitored in detail by TEM. FIG. 6 shows planar TEM images and grain size analysis images of the sample A and the sample B. FIG. 7 shows minimum particle diameters, maximum particle diameters and average particle diameters of the sample A and the sample B. As can be seen from the planar TEM images, the maximum particle diameter of the sample B was 126 μm, which is considerably greater than that of the sample A, i.e., 29 μm. The average particle diameter of the sample A was 11 μm, whereas that of the sample B was 50 μm.

From the above, it has been found that when the base of the main tungsten film is an amorphous layer, the crystal grains of the main tungsten film become greater and, thus, a tungsten film having a low resistance can be obtained.

The crystal grain diameter can be increased not only by forming the initial tungsten film 204 that is an amorphous layer but also by increasing the film formation temperature of the main tungsten film 205. In that case as well, a tungsten film having a low resistance can be obtained.

Next, specific examples of the present embodiment will be described.

### First Example

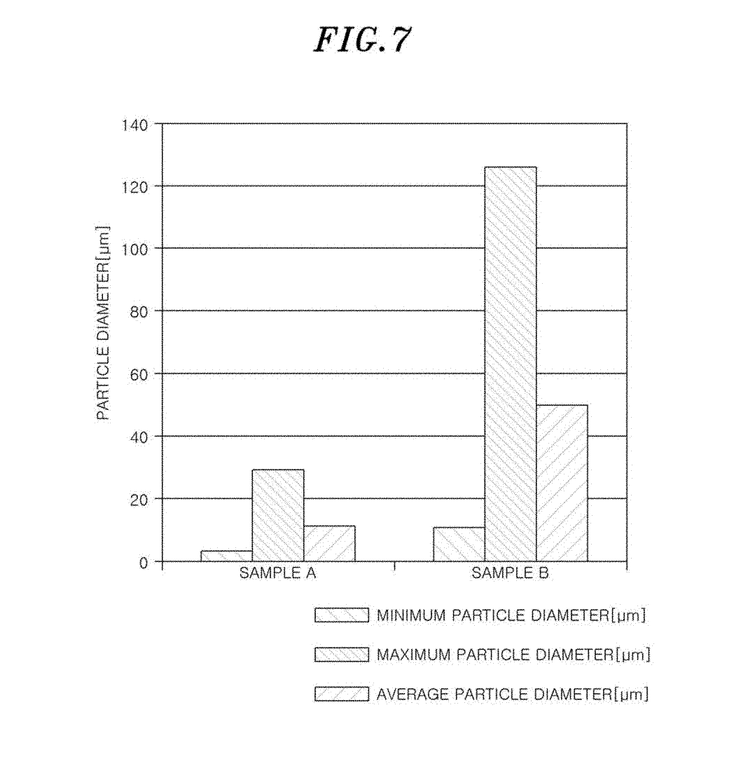

In this example, as shown in FIG. 8, the initiation process is performed by using B₂H₆ gas and H₂ gas. Then, an amorphous initial tungsten film is formed by an ALD method using WF₆ gas as a film forming gas and B₂H₆ gas as a reducing gas, and a main tungsten film is formed thereon by an ALD method using WF₆ gas as a film forming gas and H₂ gas as a reducing gas.

In the initiation process, B₂H₆ gas is used as the reducing gas so that the initial tungsten film can easily grow on the TiN film.

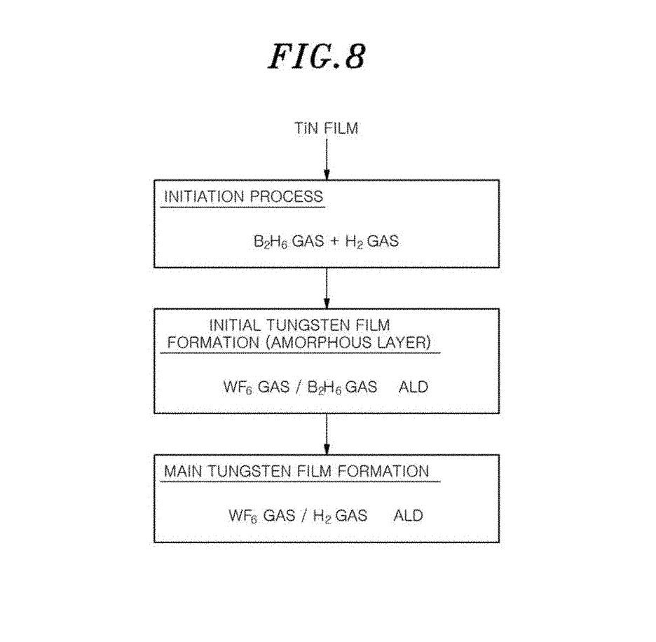

In the case of forming the initial tungsten film by the ALD method, the supply of WF₆ gas as a tungsten source gas and the supply of B₂H₆ gas as a reducing gas are repeated multiple times with purging interposed therebetween, as shown in FIG. 9. A raised portion in FIG. 9 indicates the mere purge process and does not indicate ON/OFF of the gas supply. Actually, N₂ gas is constantly supplied during the film formation, and flush purge N₂ gas is added during the purge process. In the case of forming the initial tungsten film, the initial tungsten film is amorphized by adjusting the conditions such as the supply amount and the supply period of WF₆ gas as the film forming gas and B₂H₆ gas as the reducing gas, the film formation temperature, the pressure, and the like. The conditions are set to obtain an amorphous layer. By using B₂H₆ gas as the reducing gas, it is easy to form an amorphous tungsten film.

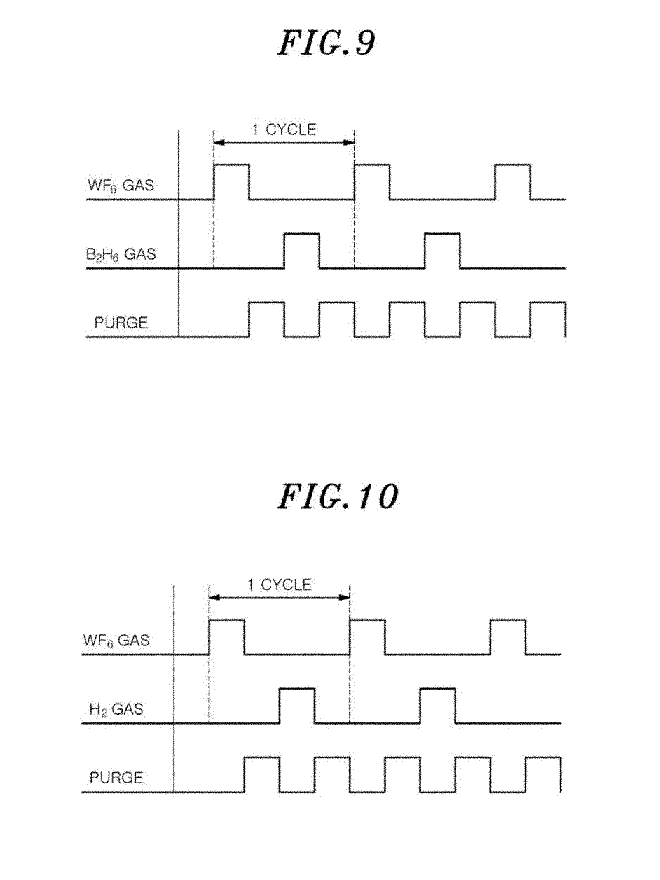

In the case of forming the main tungsten film by the ALD method, the supply of WF₆ gas as a tungsten source gas and the supply of H₂ gas as a reducing gas are repeated multiple times with purging interposed therebetween as shown in FIG. 10. N₂ gas is constantly supplied during the film formation, and flush purge N₂ gas is added during the purge process.

Hereinafter, preferable conditions of the respective steps in this example will be described.

1. Initiation Process
Temperature (susceptor temperature): 300 to 500° C.
Pressure in processing chamber; 300 to 900 Pa
Flow rate of B₂H₆ gas diluted with 5% H₂ gas: 50 to 500 sccm (mL/min)
H₂ gas flow rate: 200 to 1000 sccm (mL/min)
Time: 10 to 120 sec

2. Initial Tungsten Film Formation
Temperature (susceptor temperature): 300 to 500° C.
WF₆ gas flow rate: 50 to 500 sccm (mL/min)
Flow rate of B₂H₆ gas diluted with 5% H₂ gas: 50 to 500 sccm (mL/min)
Flow rate of continuously supplied N₂ gas: 500 to 10000 sccm (mL/min)
Flow rate of flush purge N₂ gas: 1000 to 10000 sccm (mL/min)
WF₆ gas supply period (per once): 0.1 to 10 sec
B₂H₆ gas supply period (per once): 0.1 to 10 sec
Purge (per once): 0.1 to 10 sec
Number of repetitions: 1 to 50 times

3. Main Tungsten Film Formation
Temperature (susceptor temperature): 300 to 500° C. (more preferably 350 to 450° C.)
WF₆ gas flow rate: 50 to 1000 sccm (mL/min)
H₂ gas flow rate: 2000 to 5000 sccm (mL/min)
Flow rate of continuously supplied N₂ gas: 500 to 10000 seem (mL/min)
Flow rate of flush purge N₂ gas: 1000 to 10000 sccm (mL/min)
WF₆ gas supply period (per once): 0.05 to 5 sec
H₂ gas supply period (per once): 0.05 to 5 sec
Purge (per once): 0.1 to 5 sec
Number of repetitions: appropriately set depending on a required film thickness

### Second Example

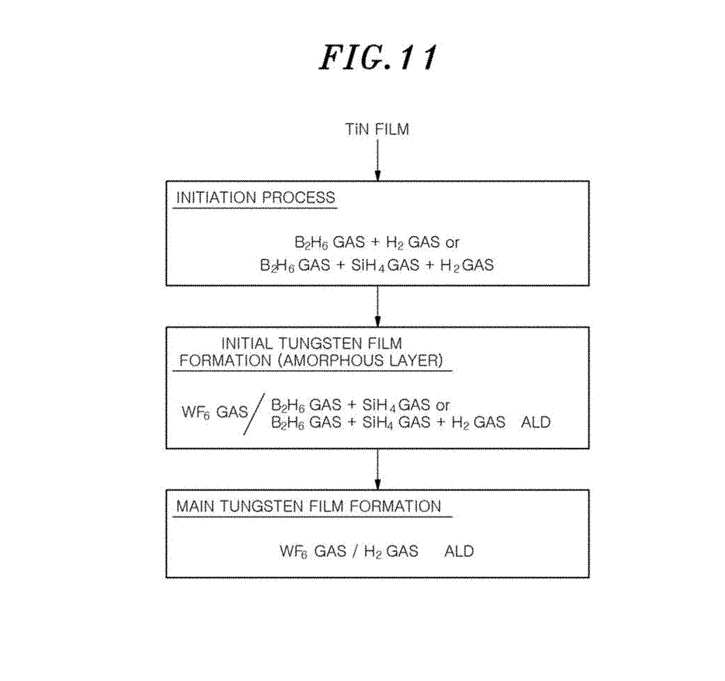

In this example, as shown in FIG. 11, the initiation process is performed by using a gaseous mixture of B₂H₆ gas and SiH₄ gas, or a gaseous mixture of B₂H₆ gas, SiH₄ gas and H₂ gas. Then, an amorphous initial tungsten film is formed by an ALD method using WF₆ gas as a film forming gas, and a gaseous mixture of B₂H₆ gas and SiH₄ gas or a gaseous mixture of B₂H₆ gas, SiH₄ gas and H₂ gas as a reducing gas. Thereafter, a main tungsten film is formed thereon by the same ALD method as that in the first example.

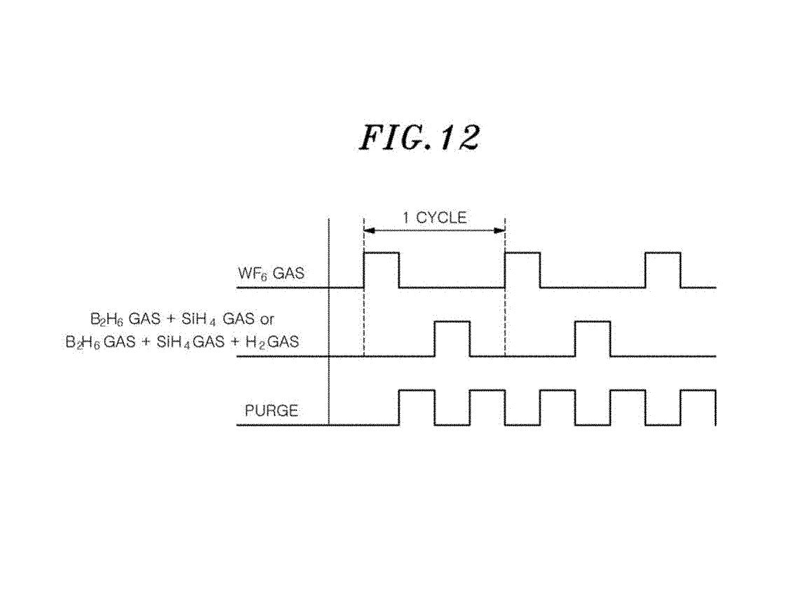

In this example, in the case of forming the initial tungsten film by the ALD method, the supply of WF₆ gas as a film forming gas and the supply of a gaseous mixture of B₂H₆ gas and SiH₄ gas or a gaseous mixture of B₂H₆ gas, SiH₄ gas and H₂ gas as a reducing gas are repeated multiple times with purging interposed therebetween as shown in FIG. 12. Then, the initial tungsten film is amorphized by adjusting the conditions such as the supply amount, the supply period, the film formation temperature, the pressure, and the like. By using a gaseous mixture of B₂H₆ gas and SiH₄ gas, or a gaseous mixture of B₂H₆ gas, SiH₄ gas and H₂ gas as the reducing gas, it is easy to amorphize the initial tungsten film.

Hereinafter, preferable conditions of the respective steps in this example will be described. Since the conditions of the main tungsten film are the same as those in the first example, redundant description thereof will be omitted.

1. Initiation Process
Temperature (susceptor temperature): 300 to 500° C.
Pressure in processing chamber: 300 to 900 Pa
Flow rate of B₂H₆ gas diluted with 5% H₂ gas: 50 to 500 sccm (mL/min)
SiH₄ gas flow rate: 50 to 500 sccm (mL/min)
H₂ gas flow rate: 200 to 1000 sccm (mL/min)
Time: 10 to 120 sec

2. Initial Tungsten Film Formation
Temperature (susceptor temperature): 300 to 500° C.
WF₆ gas flow rate: 50 to 500 sccm (mL/min)
Flow rate of B₂H₆ gas diluted with 5% H₂ gas: 50 to 500 sccm (mL/min)
SiH₄ gas flow rate: 50 to 500 sccm (mL/min)
H₂ gas flow rate: 50 to 1000 sccm (mL/min)
Flow rate of continuously supplied N₂ gas flow rate: 1000 to 10000 sccm (mL/min)
Flow rate of flush purge N₂ gas: 1000 to 10000 sccm (mL/min)
WF₆ gas supply period (per once): 0.1 to 10 sec
B₂H₆ gas supply period (per once): 0.1 to 10 sec
SiH₄ gas supply period (per once); 0.1 to 10 sec
H₂ gas supply period (per once): 0.1 to 10 sec
Purge (per once): 0.1 to 10 sec
Number of repetitions: 1 to 50 times

(Second Embodiment of Film Forming Method)

Next, a second embodiment of the film forming method will be described.

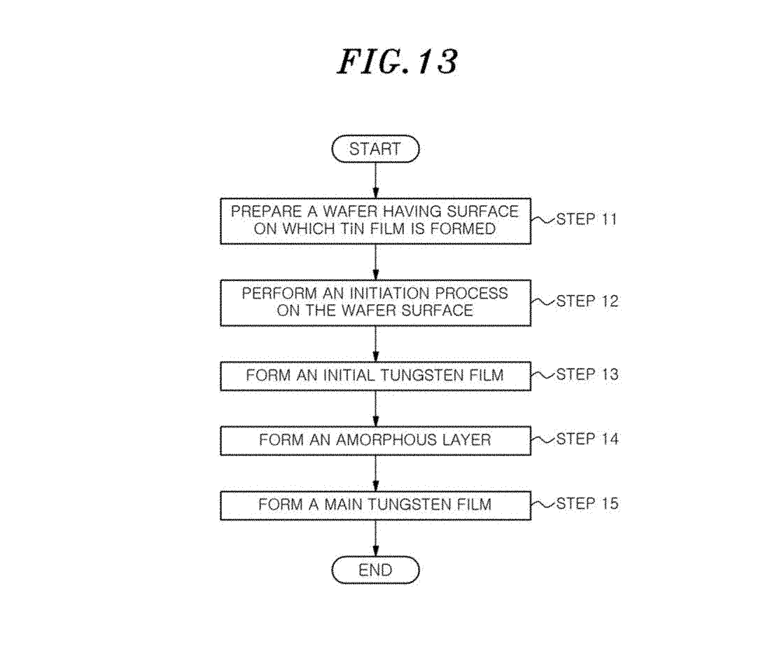

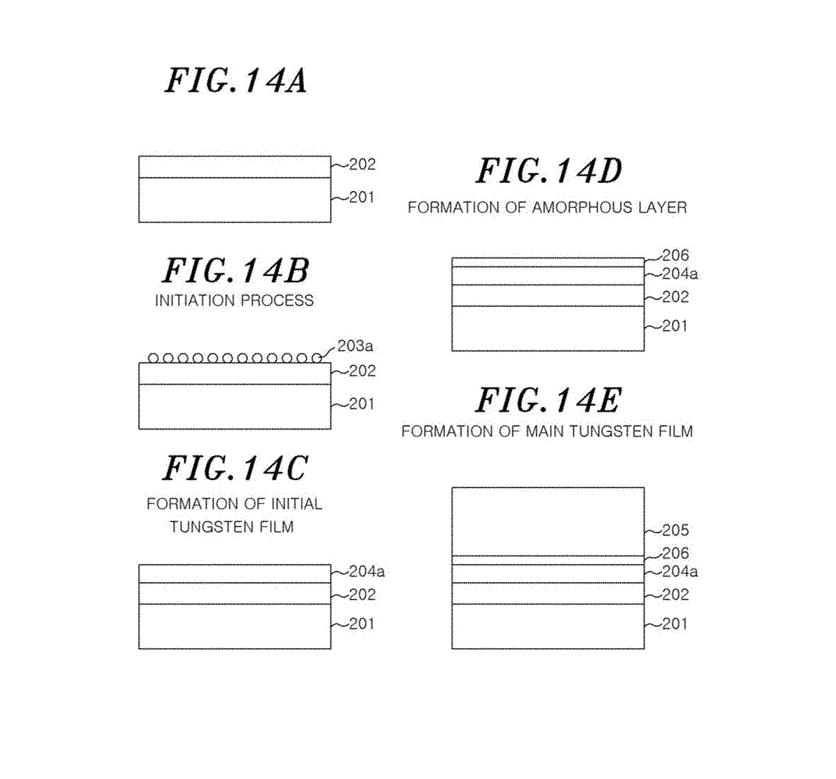

FIG. 13 is a flowchart of the second embodiment. FIGS. 14A to 14E are process cross-sectional views showing a procedure of the second embodiment.

First, as in the first embodiment, a wafer on which a TiN film 202 serving as a barrier layer is formed on an interlayer insulating film 201 made of SiO₂ or the like as shown in FIG. 14A is prepared, loaded into the chamber 1 of the film forming apparatus 100, and mounted on the susceptor 2 (STEP 11). Although a recess such as a trench, a hole (contact hole or via hole) or the like is formed in the interlayer insulating film 201, it is omitted in FIG. 14 for convenience.

Next, an atmosphere in the chamber 1 is set to a predetermined depressurized atmosphere. The wafer W on the susceptor 2 is heated to a predetermined temperature by the heater 21 in the susceptor 2, and gases, e.g., SiH₄ gas, or a gaseous mixture of SiH₄ gas and H₂ gas, or B₂H₆ gas, or a gaseous mixture of B₂H₆ gas and H₂ gas are supplied to perform an initiation process for allowing nuclei 203 to be adsorbed on the wafer surface as shown in FIG. 14B (STEP 12). Although the initiation process facilitates the formation of an initial tungsten film in a next step, it is not necessary to perform the initiation process.

Next, an initial tungsten film 204a is formed by a method in which WF₆ gas and a reducing gas (SiH₄ gas or the like) are sequentially supplied with purging of the chamber 1 interposed therebetween, e.g., an ALD method in which WF₆ gas and a reducing gas are supplied multiple times with purging of the chamber 1 interposed therebetween, from the processing gas supply mechanism 5 into the chamber 1 (STEP 13, FIG. 14C). In the present embodiment, the initial tungsten film 204 is a crystalline layer. The film thickness of the initial tungsten film 204a is preferably 0.5 nm to 5 nm.

Next, an amorphous layer 206 is formed by allowing a gas containing a material for nucleation, e.g., a gas containing B₂H₆ gas, to be adsorbed on the surface of the initial tungsten film 204a (STEP 14, FIG. 14D). The amorphous layer 206 may be thick enough to cover the surface of the initial tungsten film 204a thereunder. The film thickness of the amorphous layer 206 is preferably 0.5 nm to 5 nm.

Next, a main tungsten film 205 is formed on the amorphous layer 206 (STEP 15, FIG. 14E). As in the first embodiment, the main tungsten film 205 is formed by the method in which gases are sequentially supplied, e.g., the ALD method.

By forming the amorphous layer 206 prior to the formation of the main tungsten film 205, the main tungsten film 205 can be easily formed and, also, the number of nuclei of tungsten can be decreased. Accordingly, the crystal grain diameter can be increased, and the resistance of the tungsten film can be lowered.

Since the tungsten film 205 can be formed with high step coverage by the method in which gases are sequentially supplied such as the ALD method, satisfactory fillability can be obtained even in a fine recess having a high aspect ratio.

Next, a specific example of the present embodiment will be described.

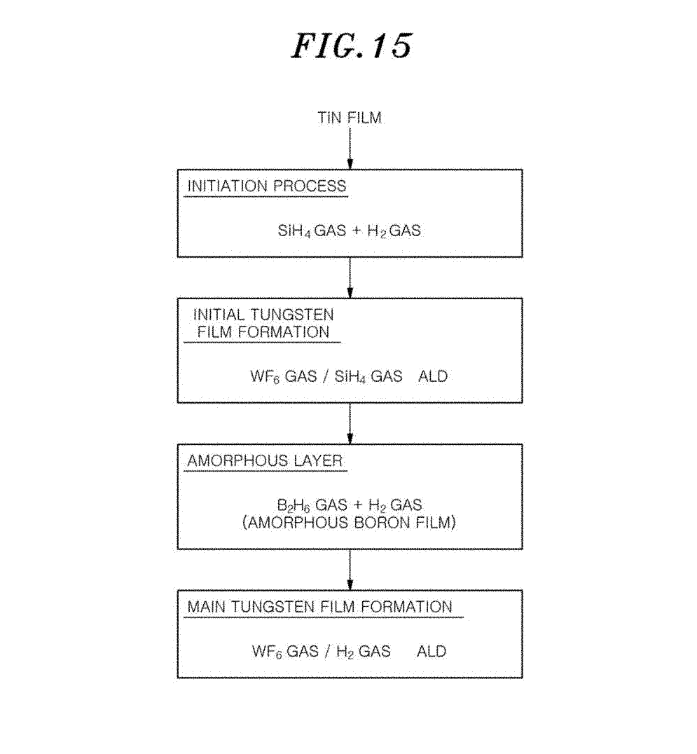

In this example, as shown in FIG. 15, an initiation process is performed by using SiH₄ gas and H₂ gas. Then, an initial tungsten film is formed by an ALD method using WF₆ gas as a film forming gas and SiH₄ gas as a reducing gas. Then, an amorphous layer is formed thereon by using B₂H₆ gas and H₂ gas. Then, a main tungsten film is formed thereon by an ALD method using WF₆ gas as a film forming gas and H₂ gas as a reducing gas.

In the initiation process, SiH₄ gas used as a reducing gas in forming the initial tungsten film is used as a nucleation gas so that the initial tungsten film can easily grow on the TiN film.

In the case of forming the initial tungsten film by the ALD method, the supply of WF₆ gas as the tungsten source gas and the supply of SiH₄ gas as the reducing gas are repeated multiple times with purging interposed therebetween. Accordingly, the initial tungsten film that is a crystalline layer is formed.

In the formation of the amorphous layer, a film of a material for nucleation is formed by performing a nucleation process similar to the initiation process on the surface of the initial tungsten film for a long period of time. By using B₂H₆ gas and H₂ gas, B material for nucleation becomes an amorphous boron film.

Here, the amorphous boron film is formed using B₂H₆ gas by the following method.

The substrate is processed under the conditions:

Film forming temperature: 400° C., 450° C. and 500° C.

Film forming pressure: 500 Pa

Flow rate of B₂H₆ gas diluted with 5% H₂ gas: 100 sccm

Flow rate of continuously supplied N₂ gas: 6000 sccm

Processing time: 20 sec and 60 sec

B intensity of XRF was 0.8057 kcps and 0.8151 kcps under the respective conditions of 400° C. and 20 sec and 400° C. and 60 sec; 0.8074 kcps and 2.0388 kcps under the respective conditions of 450° C. and 20 sec and 450° C. and 60 sec; and 0.9271 kcps and 3.905 kcps under the respective conditions of 500° C. and 20 sec and 500° C. and 60 sec. Boron SEM film thicknesses equivalent to these intensities were substantially 0 nm under the conditions of 400° C. and 20 sec and 400° C. and 60 sec; substantially 0 nm under the condition of 450° C. and 20 sec; 6.9 nm under the condition of 450° C. and 60 sec; 0.4 nm under the condition of 500° C. and 20 sec; and 17.8 nm under the condition of 500° C. and 60 sec.

According to the XRD analysis of the crystallinity of the film formed under the condition of 450° C. and 60 sec, a broad peak was observed and the film was determined to be amorphous.

In the case of supplying B₂H₆ gas diluted with 5% H₂ gas to the substrate under the above conditions, an amorphous boron film having a desired thickness can be obtained by controlling the temperature and the supply period of time.

Hereinafter, preferable conditions of the respective steps in this example will be described. The conditions of the initiation process are the same as those in the second example of the first embodiment, and the conditions of the main tungsten film formation are the same as those in the first example of the first embodiment. Therefore, redundant description thereof will be omitted.

1. Initial Tungsten Film Formation
Temperature (susceptor temperature): 350 to 500° C.
WF₆ gas flow rate: 50 to 500 sccm (mL/min)
SiH₄ gas flow rate: 50 to 500 sccm (mL/min)
Flow rate of continuously supplied N₂ gas: 1000 to 10000 sccm (mL/min)
Flow rate of flush purge N₂ gas: 1000 to 10000 sccm (mL/min)
WF₆ gas supply time (per once): 0.1 to 10 sec
SiH₄ gas supply time (per once): 0.1 to 10 sec
Purge (per once): 0.1 to 10 sec
Number of repetitions: 1 to 50 times

2. Formation of Amorphous Layer
Temperature (susceptor temperature): 350 to 500° C.
Pressure in processing chamber; 300 to 900 Pa
B₂H₆ gas flow rate: 50 to 500 sccm (mL/min)
H₂ gas flow rate: 200 to 1000 sccm (mL/min)
Time: 10 to 120 sec

(Third Embodiment of Film Forming Method)

Next, a third embodiment of the film forming method will be described.

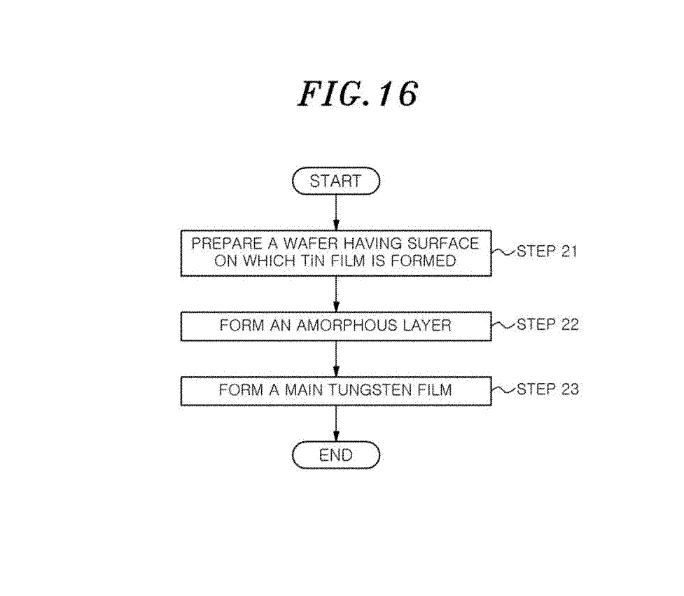

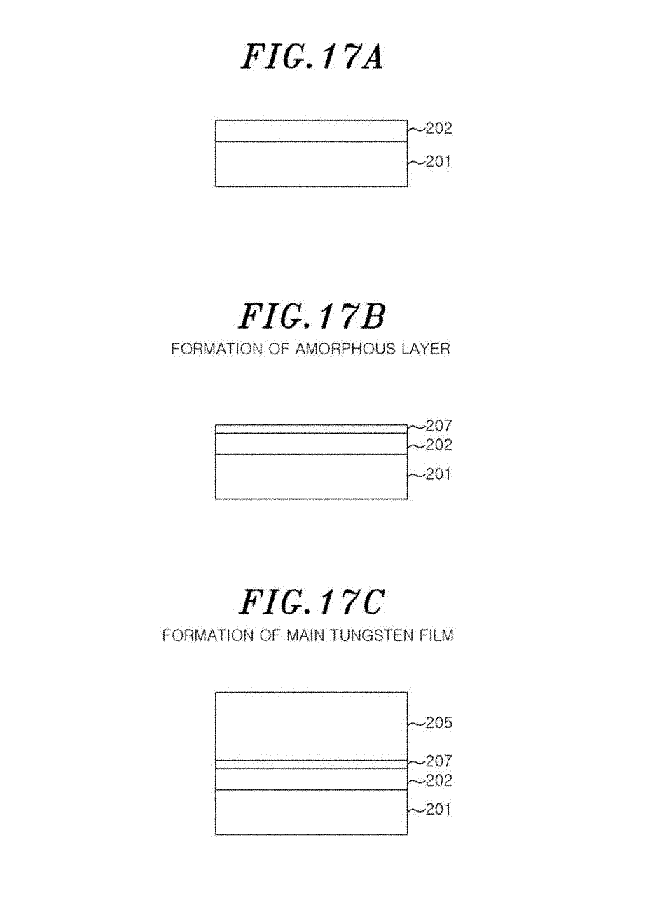

FIG. 16 is a flowchart of the third embodiment. FIGS. 17A to 17C are process cross-sectional views showing a procedure of the third embodiment.

First, as in the first embodiment, a wafer on which a TiN film 202 serving as a barrier film is formed on an interlayer insulating film 201 made of SiO₂ or the like as shown in FIG. 17A is prepared, loaded into the chamber 1, and mounted on the susceptor 2 (STEP 21). Although a recess such as a trench, a hole (contact hole or via hole) or the like is formed in the interlayer insulating film 201, it is omitted in FIGS. 17A to 17C for convenience.

Next, an atmosphere in the chamber 1 is set to a predetermined depressurized atmosphere. The wafer W on the susceptor 2 is heated to a predetermined temperature by the heater 21 in the susceptor 2, and a gas containing SiH₄ gas is supplied and adsorbed on the surface of the TiN film 202 to form an amorphous layer 207 (STEP 22, FIG. 17B). The amorphous layer 207 may be thick enough to cover the surface of the TiN film 202 thereunder. The film thickness of the amorphous layer 207 is preferably 0.5 nm to 5 nm.

Next, in a state where the heating temperature of the susceptor 2 is maintained, a main tungsten film 205 is formed on the amorphous layer 207 (STEP 23, FIG. 17C). As in the first embodiment, the main tungsten film 205 is formed by the method in which gases are sequentially supplied, e.g., the ALD method.

By forming the amorphous layer 207 prior to the formation of the main tungsten film 205, the main tungsten film 205 can be easily formed, and the number of nuclei of tungsten can be decreased. Accordingly, the crystal grain diameter can be increased, and the resistance of the tungsten film can be lowered.

Since the tungsten film 205 can be formed with high step coverage by the method in which gases are sequentially supplied, such as the ALD method or the like, satisfactory fillability can be obtained even in a fine recess having a high aspect ratio.

In addition, since the initial tungsten film is not required, the processing can be simplified.

Next, a specific example of the present embodiment will be described.

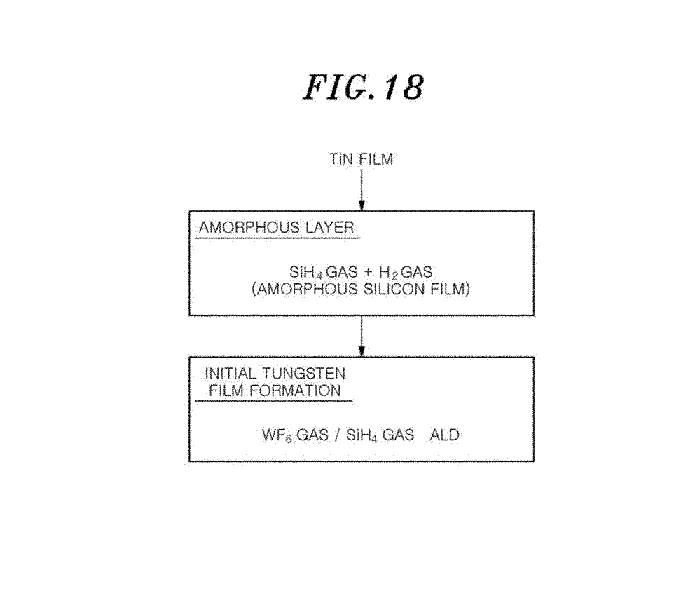

In this example, as shown in FIG. 18, an amorphous layer is formed by using SiH₄ gas and H₂ gas, and a main tungsten film is formed by an ALD method using WF₆ gas as a film forming gas and H₂ gas as a reducing gas.

In the formation of the amorphous layer, a film of a material for nucleation is formed by performing a nucleation process similar to the initiation process on the surface of the TiN film for a long period of time. By using SiH₄ gas and H₂ gas, Si material for nucleation becomes an amorphous silicon film.

Hereinafter, preferable conditions of the respective steps in this example will be described. Since the main tungsten film formation conditions are the same as those in the first example of the first embodiment, redundant description thereof will be omitted.

1. Amorphous Layer Formation
Temperature (susceptor temperature): 300 to 500° C.
Pressure in processing chamber: 300 to 900 Pa
SiH₄ gas flow rate: 50 to 500 sccm (mL/min)
H₂ gas flow rate: 0 to 1000 sccm (mL/min)
Time: 10 to 120 sec

(Fourth Embodiment of Film Forming Method)

Next, a fourth embodiment of the film forming method will be described.

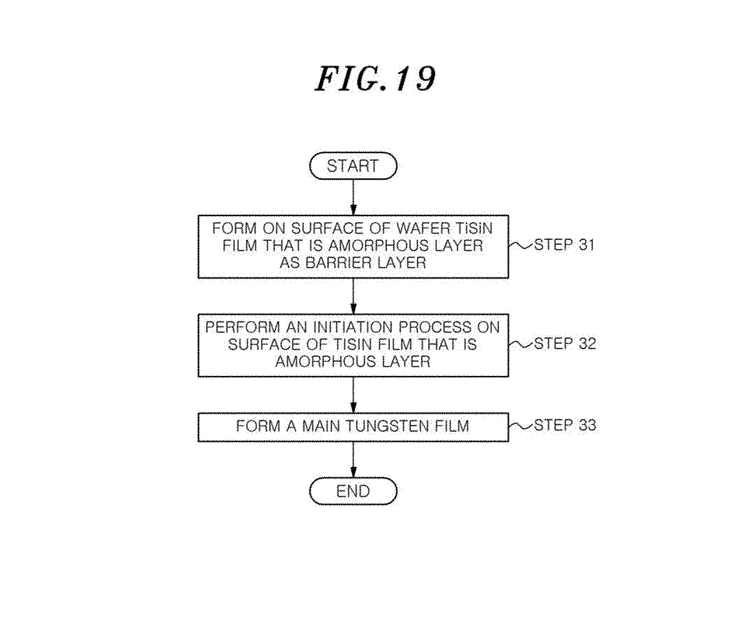

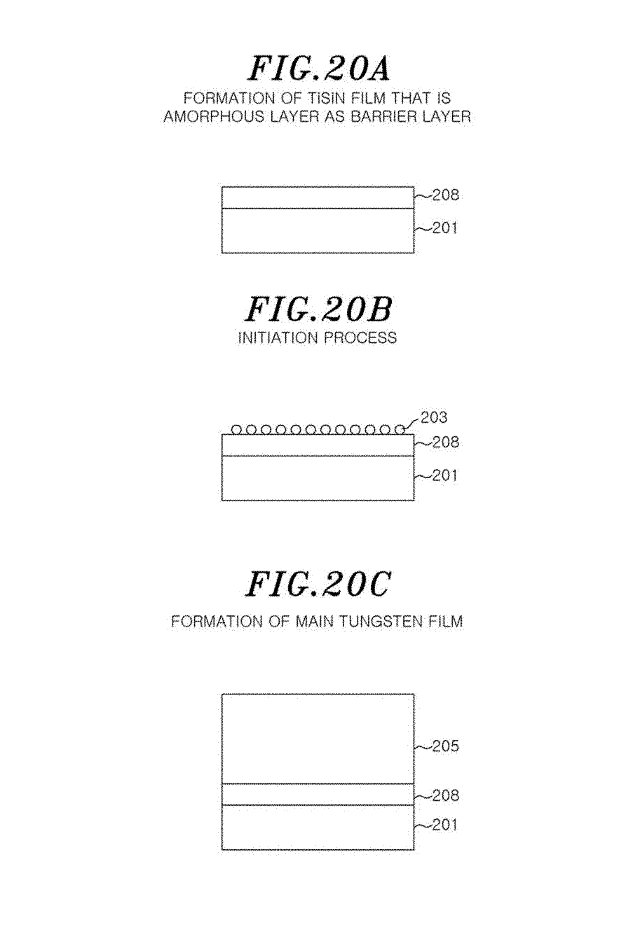

FIG. 19 is a flowchart of the fourth embodiment. FIGS. 20A to 20C are process cross-sectional views showing a procedure of the fourth embodiment.

First, as shown in FIG. 20A, with respect to a wafer having an interlayer insulating film 201 made of SiO₂ or the like, a TiSiN film 208 that is an amorphous layer is formed as a barrier layer on the interlayer insulating film 201 by a separate apparatus (STEP 31). Although a recess such as a trench, a hole (contact hole or via hole) or the like is formed in the interlayer insulating film 201, it is omitted in FIGS. 20A to 20C for convenience.

Next, the wafer on which the TiSiN film 208 is formed is loaded into the chamber 1 and mounted on the susceptor 2. Then, an atmosphere in the chamber 1 is set to a predetermined depressurized atmosphere. Thereafter, as shown in FIG. 20B, an initiation process for allowing the nuclei 203 to be adsorbed on the wafer surface is started by supplying SiH₄ gas, or a gaseous mixture of SiH₄ gas and H₂ gas, or B₂H₆ gas, or a gaseous mixture of B₂H₆ gas and H₂ gas while heating the wafer on the susceptor 2 to a predetermined temperature by the heater 21 in the susceptor 2 (STEP 32). Although the initiation process is performed to facilitate the main tungsten film formation in a next step, it is required to perform the initiation process and the formation of the main tungsten film 205 in-situ with the formation of a TiSiN film 208 that is an amorphous layer in order to maintain the surface activity of the TiSiN film 208. However, it is not necessary to perform the initiation process.

Next, the main tungsten film 205 is formed on the TiSiN film 208 that is an amorphous layer (STEP 33, FIG. 20C). As in the first embodiment, the main tungsten film 205 is formed by the method in which gases are sequentially supplied, e.g., the ALD method.

Since the TiSiN film 208 that is an amorphous layer is formed as a barrier layer of a base film, when the main tungsten film 205 is formed thereon, the number of nuclei of tungsten can be decreased. Accordingly, the crystal grain diameter can be increased, and the resistance of the tungsten film can be lowered.

Since the tungsten film 205 can be formed with high step coverage by the method in which gases are sequentially supplied, e.g., the ALD method or the like, satisfactory fillability can be obtained even in a fine recess having a high aspect ratio.

Further, since the main tungsten film 205 is formed on the base film that is an amorphous layer with the initiation process interposed therebetween, the initial tungsten film becomes unnecessary and the processing can be simplified.

As for the amorphous layer serving as the base of the main tungsten film 205, various films other than the TiSiN film can be used. For example, it is possible to use an amorphous molybdenum film formed by CVD or ALD using an organic molybdenum film as a raw material.

Next, a specific example of this embodiment will be described.

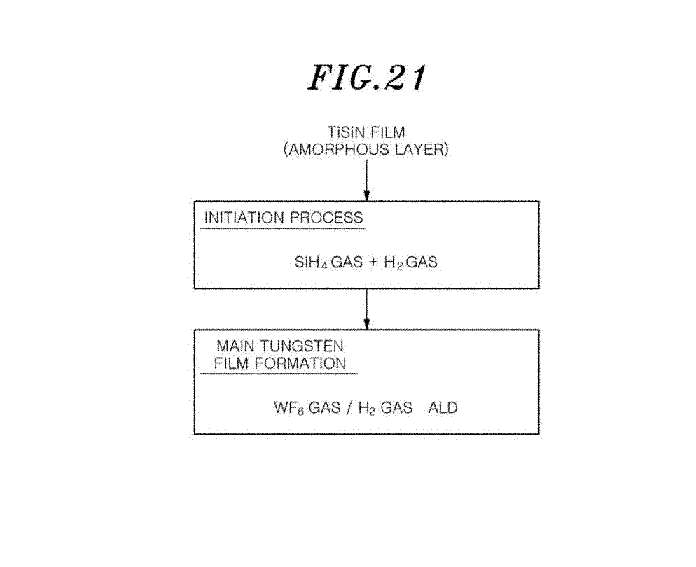

In this example, as shown in FIG. 21, the TiSiN film 208 that is an amorphous layer is formed and, then, the initiation process is performed thereon in-situ by SiH₄ gas and H₂ gas. Next, the main tungsten film is formed by the ALD method using WF₆ gas as a film forming gas and H₂ gas as a reducing gas. The conditions of the initiation process are the same as those in the second example of the first embodiment, and the conditions of the main tungsten film formation are the same as those in the first example of the first embodiment.

### Other Applications

Although the embodiments of the present invention have been described, the present invention is not limited to the above-described embodiments and can be variously modified.

The above-described embodiments have described the example in which the main tungsten film is formed by the method in which gases are sequentially supplied such as the ALD method. However, the present invention can also be applied to the case in which the main tungsten film is formed by a CVD method.

Although the above-described embodiments have described the examples in which the base of the main tungsten film is an amorphous layer, the material of the amorphous layer is not limited thereto.

Although a semiconductor wafer has been described as an example of a target substrate, the semiconductor wafer may be silicon or may be a compound semiconductor such as GaAs, SiC, GaN, or the like. Further, the present invention can also be applied to a glass substrate used for FPD (Flat Panel Display) such as a liquid crystal display or the like, a ceramic substrate, or the like without being limited to a semiconductor wafer.

### DESCRIPTION OF REFERENCE NUMERALS

| 1: chamber | 2: susceptor |
|---|---|
| 3: shower head | 4: gas exhaust unit |
| 5: gas supply mechanism | 6: control unit |
| 21: heater | 51: WF₆ gas supply source |
| 52: H₂ gas supply source | 53: SiH₄ gas supply source |
| 54: B₂H₆ gas supply source | |
| 55: first N₂ gas supply source | |
| 56: second N₂ gas supply source | |
| 61: WF₆ gas supply line | 62: H₂ gas supply line |
| 63: SiH₄ gas supply line | 64: B₂H₆ gas supply line |
| 65: first N₂ gas supply line | |
| 66: second N₂ gas supply line | |
| 67: first continuous N₂ gas supply line | |
| 68: first flush purge line | |
| 69: second continuous N₂ gas supply line | |
| 70: second flush purge line | |
| 73, 74, 75, 76, 77, 78, 79: opening/closing valve | |
| 100: film forming apparatus | |
| 201: interlayer insulating film | |
| 202: TiN film | 203: nuclei |
| 203a: adsorbate | |
| 204: initial tungsten film (amorphous layer) | |
| 204a: initial tungsten film | |
| 205: main tungsten film | 206, 207: amorphous layer |

208: TiSiN film (amorphous layer)
W: semiconductor wafer (target substrate)

1. A tungsten film forming method for forming a tungsten film on a surface of a substrate, the method comprising:
disposing a substrate having an amorphous layer on a surface thereof in a processing chamber under a depressurized atmosphere;
heating the substrate in the processing chamber; and
forming a main tungsten film on the amorphous layer by supplying into the processing chamber WF₆ gas as a tungsten source gas and H₂ gas as a reducing gas.

2. The tungsten film forming method of claim 1, wherein the substrate has a TiN film on the surface thereof.

3. The tungsten film forming method of claim 1, wherein the substrate is heated to a temperature of 300° C. to 500° C.

4. The tungsten film forming method of claim 3, wherein the substrate is heated to a temperature of 350° C. to 450° C.

5. The tungsten film forming method of claim 1, wherein the main tungsten film is formed by sequentially supplying WF₆ gas as the tungsten source gas and H₂ gas as the reducing gas into the processing chamber with purging of the processing chamber interposed therebetween.

6. A tungsten film forming method for forming a tungsten film on a surface of a substrate, the method comprising:
disposing a substrate in a processing chamber under a depressurized atmosphere;
heating the substrate in the processing chamber;
forming an initial tungsten film that is an amorphous layer on the surface of the substrate by sequentially supplying into the processing chamber WF₆ gas as a tungsten source gas and a reducing gas with purging of the processing chamber interposed therebetween; and
forming a main tungsten film on the initial tungsten film by supplying into the processing chamber WF₆ gas as a tungsten source gas and H₂ gas as a reducing gas.

7. The tungsten film forming method of claim 6, wherein the initial tungsten film is formed by using B₂H₆ gas as the reducing gas.

8. The tungsten film forming method of claim 6, wherein the initial tungsten film is formed by using a gaseous mixture of B₂H₆ gas and SiH₄ gas, or a gaseous mixture of B₂H₆ gas, SiH₄ gas and H₂ gas as the reducing gas.

9. The tungsten film forming method of claim 6, further comprising, before said forming the initial tungsten film that is the amorphous layer, performing an initiation process for facilitating the formation of the initial tungsten film that is the amorphous layer.

10. The tungsten film forming method of claim 9, wherein the initiation process is performed on the surface of the substrate by supplying SiH₄ gas, or a gaseous mixture of SiH₄ gas and H₂ gas, or B₂H₆ gas, or a gaseous mixture of B₂H₆ gas and H₂ gas.

11. The tungsten film forming method of claim 6, wherein the substrate has a TiN film on the surface thereof.

12. The tungsten film forming method of claim 6, wherein the substrate is heated to a temperature of 300° C. to 500° C.

13. The tungsten film forming method of claim 12, wherein the substrate is heated to a temperature of 350° C. to 450° C.

14. The tungsten film forming method of claim 6, wherein the main tungsten film is formed by sequentially supplying WF₆ gas as the tungsten source gas and H₂ gas as the reducing gas into the processing chamber with purging of the processing chamber interposed therebetween.

15. A tungsten film forming method for forming a tungsten film on a surface of a substrate, the method comprising:
disposing a substrate in a processing chamber under a depressurized atmosphere;
heating the substrate in the processing chamber;
forming an initial tungsten film that is a crystalline layer on the surface of the substrate by sequentially supplying WF₆ gas as a tungsten source gas and a reducing gas into the processing chamber with purging of the processing chamber interposed therebetween;
forming an amorphous layer on the initial tungsten film; and
forming a main tungsten film on the amorphous layer by supplying WF₆ gas as a tungsten source gas and H₂ gas as a reducing gas into the processing chamber.

16. The tungsten film forming method of claim 15, wherein the initial tungsten film is formed by using SiH₄ gas as the reducing gas.

17. The tungsten film forming method of claim 15, wherein a gas containing a material of the amorphous layer is a gaseous mixture of B₂H₆ gas and H₂ gas, or a gaseous mixture of B₂H₆ gas, H₂ gas and WF₆ gas, and the amorphous layer is an amorphous boron film or an amorphous tungsten film.

18. The tungsten film forming method of claim 15, further comprising, before said forming the initial tungsten film, performing an initiation process for facilitating the formation of the initial tungsten film on the surface of the substrate.

19. The tungsten film forming method of claim 18, wherein the initiation process is performed on the surface of the substrate by supplying SiH₄ gas, or a gaseous mixture of SiH₄ gas and H₂ gas, or B₂H₆ gas, or a gaseous mixture of B₂H₆ gas and H₂ gas.

20. The tungsten film forming method of claim 15, wherein the substrate has a TiN film on the surface thereof.

21. The tungsten film forming method of claim 15, wherein the substrate is heated to a temperature of 300° C. to 500° C.

22. The tungsten film forming method of claim 21, wherein the substrate is heated to a temperature of 350° C. to 450° C.

23. The tungsten film forming method of claim 15, wherein the main tungsten film is formed by sequentially supplying WF₆ gas as the tungsten source gas and H₂ gas as the reducing gas into the processing chamber with purging of the processing chamber interposed therebetween.

24. A tungsten film forming method for forming a tungsten film on a surface of a substrate, the method comprising:
disposing a substrate in a processing chamber under a depressurized atmosphere;
heating the substrate in the processing chamber,
forming an amorphous layer on the surface of the substrate; and
forming a main tungsten film on the amorphous layer by supplying WF₆ gas as a tungsten source gas and H₂ gas as a reducing gas into the processing chamber.

25. The tungsten film forming method of claim 24, wherein a gas for forming the amorphous layer is SiH₄ gas or B₂H₆ gas, or a gaseous mixture thereof, and the amorphous layer is an amorphous silicon film or an amorphous boron film.

26. The tungsten film forming method of claim 24, wherein the substrate has a TiN film on the surface thereof.

27. The tungsten film forming method of claim 24, wherein the substrate is heated to a temperature of 300° C. to 500° C.

28. The tungsten film forming method of claim 27, wherein the substrate is heated to a temperature of 350° C. to 450° C.

29. The tungsten film forming method of claim 24, wherein the main tungsten film is formed by sequentially supplying WF₆ gas as the tungsten source gas and H₂ gas as the reducing gas into the processing chamber with purging of the processing chamber interposed therebetween.

30. A tungsten film forming method for forming a tungsten film on a surface of a substrate, the method comprising:
preparing a substrate;
forming an amorphous layer on the surface of the substrate;
heating the substrate in a processing chamber under a depressurized atmosphere; and
forming a main tungsten film on the amorphous layer by supplying WF₆ gas as a tungsten source gas and H₂ gas as a reducing gas into the processing chamber.

31. The tungsten film forming method of claim 30, wherein said forming the amorphous layer on the substrate and said forming the main tungsten film are performed in-situ.

32. The tungsten film forming method of claim 30, further comprising, before said forming the main tungsten film, performing an initiation process for facilitating the formation of the main tungsten film on the amorphous layer formed on the surface of the substrate.

33. The tungsten film forming method of claim 32, wherein the initiation process is performed on the surface of the substrate by supplying SiH₄ gas, or a gaseous mixture of SiH₄ gas and H₂ gas, or B₂H₆ gas, or a gaseous mixture of B₂H₆ gas and H₂ gas.

34. The tungsten film forming method of claim 32, wherein said forming the amorphous layer on the substrate, said performing the initiation process, and said forming the main tungsten film are performed in-situ.

35. The tungsten film forming method of claim 30, wherein the amorphous layer formed on the surface of the substrate is a TiSiN film.

36. The tungsten film forming method of claim 30, wherein the substrate is heated is to a temperature of 300° C. to 500° C.

37. The tungsten film forming method of claim 36, wherein the substrate is heated is to a temperature of 350° C. to 450° C.

38. The tungsten film forming method of claim 30, wherein the main tungsten film is formed by sequentially supplying WF₆ gas as the tungsten source gas and H₂ gas as the reducing gas into the processing chamber with purging of the processing chamber interposed therebetween.

39. A non-transitory storage medium storing a program that is executed on a computer to control a film forming apparatus to form a tungsten film on a surface of a substrate, wherein the program, when executed on the computer, controls the film forming apparatus to:
dispose the substrate having an amorphous layer on the surface thereof in a processing chamber under a depressurized atmosphere;
heat the substrate in the processing chamber; and
form a main tungsten film on the amorphous layer by supplying into the processing chamber WF₆ gas as a tungsten source gas and H₂ gas as a reducing gas.

40. A non-transitory storage medium storing a program that is executed on a computer to control a film forming apparatus to form a tungsten film on a surface of a substrate, wherein the program, when executed on the computer, controls the film forming apparatus to:
dispose the substrate in a processing chamber under a depressurized atmosphere;
heat the substrate in the processing chamber;
form an initial tungsten film that is an amorphous layer on the surface of the substrate by sequentially supplying into the processing chamber WF₆ gas as a tungsten source gas and a reducing gas with purging of the processing chamber interposed therebetween;
form a main tungsten film on the initial tungsten film by supplying into the processing chamber WF₆ gas as a tungsten source gas and H₂ gas as a reducing gas.

41. A non-transitory storage medium storing a program that is executed on a computer to control a film forming apparatus to form a tungsten film on a surface of a substrate, wherein the program, when executed on the computer, controls the film forming apparatus to:
dispose the substrate in a processing chamber under a depressurized atmosphere;
heat the substrate in the processing chamber;
form an initial tungsten film that is a crystalline layer on the surface of the substrate by sequentially supplying WF₆ gas as a tungsten source gas and a reducing gas into the processing chamber with purging of the processing chamber interposed therebetween;
form an amorphous layer on the initial tungsten film; and
form a main tungsten film on the amorphous layer by supplying WF₆ gas as a tungsten source gas and H₂ gas as a reducing gas into the processing chamber.

42. A non-transitory storage medium storing a program that is executed on a computer to control a film forming apparatus to form a tungsten film on a surface of a substrate, wherein the program, when executed on the computer, controls the film forming apparatus to:
dispose the substrate in a processing chamber under a depressurized atmosphere;
heat the substrate in the processing chamber;
form an amorphous layer on the surface of the substrate; and
form a main tungsten film on the amorphous layer by supplying WF₆ gas as a tungsten source gas and H₂ gas as a reducing gas into the processing chamber.

43. A non-transitory storage medium storing a program that is executed on a computer to control a film forming apparatus to form a tungsten film on a surface of a substrate, wherein the program, when executed on the computer, controls the film forming apparatus to:
prepare a substrate;
form an amorphous layer on the surface of the substrate,
heat the substrate in a processing chamber under a depressurized atmosphere, and
form a main tungsten film on the amorphous layer by supplying WF₆ gas as a tungsten source gas and H₂ gas as a reducing gas into the processing chamber.
